(19) United States
(12) Patent Application Publication
(10) Pub. No.: US 2025/0183193 A1
(43) Pub. Date: Jun. 5, 2025

(54) DESIGN TECHNIQUES FOR HIGH-FREQUENCY AND HIGH-SPEED SIGNALS IN A PACKAGE WITH THIN BUILD-UP LAYERS

(71) Applicant: Telefonaktiebolaget LM Ericsson (publ), Stockholm (SE)

(72) Inventors: Martin HANSSON, Löddeköpinge (SE); Agneta LJUNGBRO, Bjärred (SE); Peter SVENSSON, Lund (SE); Raihan RAFIQUE, Lund (SE)

(21) Appl. No.: 18/843,219

(22) PCT Filed: Apr. 24, 2023
(86) PCT No.: PCT/EP2023/060654

§ 371 Date: Aug. 30, 2024

Related U.S. Application Data
(60) Provisional application No. 63/363,818, filed on Apr. 29, 2022.

(51) Int. Cl. H01L 23/552; H01L 23/498

(52) U.S. Cl. CPC H01L 23/552; H01L 23/49816

(57) ABSTRACT

A package for assembling one or more integrated circuits and routing signals of the one or more integrated circuits using multiple redistribution layers and a method for shielding a signal pad of an integrated circuit in the package are disclosed. The top layer of the redistribution layers is facing the integrated circuit, the bottom layer of the redistribution layers is an interface layer facing a substrate or PCB. A shielding structure is provided on the top layer of the redistribution layers above a signal pad of an integrated circuit. The signal pad is on the bottom layer of the redistribution layers and is used for routing high-frequency or high-speed signals.

### TECHNICAL FIELD

Embodiments herein relate to design techniques for high-frequency and high-speed signals in a package. In particular, they relate to design techniques for routing and protecting high-frequency and high-speed signals in a High-Density Fan Out package with redistribution layers.

### BACKGROUND

A wireless communication device or equipment usually comprises an antenna, a transceiver comprising a transmitter (Tx) and a receiver (Rx), and a baseband processing unit. The transmitter typically up-converts baseband signals to Radio Frequency (RF) signals for transmission, and the receiver down-converts received RF signals to baseband signals for further processing in the baseband processing unit. Usually, the transceiver with RF function is integrated on a silicon chip and the baseband processing unit with digital function is integrated on another silicon chip. RF chip and baseband chip each may be refereed as a chiplet. A chiplet is a tiny integrated circuit (IC) that contains a well-defined subset of functionality. It is designed to be combined with other chiplets on an interposer in a single package.

In high frequency band RF ICs, there is limited silicon die area under the antenna for integration of beamforming IC. For some solutions there is a need to integrate both RF and digital functions in a very limited silicon die area. The silicon die area is shrinking with the increasing of frequency by a relation of 1/f², and new ways of packaging are needed for matching this. In case of multiple process nodes, for minimizing silicon area and lowering power, a package technology like a High-Density Fan Out (HDFO) type of package is needed.

In HDFO package thin redistribution layers (RDL) are built up by thin film technology on a wafer or a panel. Compared to traditional laminate substrate packages the layers are very thin, often 10 times thinner.

The RDL interposers enable high-density routing between different silicon dies and to do fan-out to other package substrates or Printed Circuit Board (PCBs).

The HDFO packages are typically used to connect chiplets with thin RDL layers using a wide parallel interface, many wires with rather low speed signals but very short distance, e.g. typically 100 μm. However, this type of package has its limitations when used for RF and high-speed signals. Specific caution needs to be taken not to get too high capacitive load from the very thin layers and large pads, e.g. via pads or solder ball pads.

Routing high frequency signals, e.g. RF, millimeter (mm) Wave signals and high-speed digital signals on thin RDL layers, with a transition to PCB or High Density Interconnect (HDI) laminate through a solder ball interface, results in an impedance mismatch in the solder ball transition. This is due to the large parasitic capacitance from the relatively large solder ball pad and close proximity to a ground (GND) plane in the RDL due to the thin RDL dielectric layers. There are usually GND planes in all levels of a package or a board. The GND plane of the RDL is connected to a GND plane of the next package level, PCB or HDI laminate, through solder-balls. A ground plane on a PCB is a large area or layer of copper foil connected to a circuit's ground point, usually one terminal of a power supply. It serves as a return path for current from many different components.

A common technique to reduce the impact of parasitic capacitance due to large pads and close proximity to the GND planes, is to open up holes on GND layers above the pad, i.e. to make anti-pads. An anti-pad is a void area around a via on a copper plane, e.g. a GND layer. For an RDL with very thin dielectrics layers this technique requires the GND layers to be opened all the way through the RDL stack-up. This exposes the RF, mmWave and high-speed digital signals to the external, risking electro-magnetic coupling to and from the normally sensitive RF, mmWave and high-speed digital signals, which could lead to RF spurious signals or noise.

### SUMMARY

It is therefore an object of embodiments herein to provide an improved design technique for assembling chiplets and routing sensitive high-frequency and high-speed signals in a HDFO package or any other package technologies using very thin build-up layers.

According to one aspect of embodiments herein, the object is achieved by a method for shielding a signal pad of an integrated circuit in a package with multiple redistribution layers, wherein a top layer of the redistribution layers is facing the integrated circuit, a bottom layer of the redistribution layers is an interface layer facing a substrate or PCB, and the signal pad is on the bottom layer of the redistribution layers and is used for routing high-frequency or high-speed signals. The method comprises providing a shielding structure on the top layer of the redistribution layers above the signal pad.

According to some embodiments herein, the shielding structure may be a meshed top layer of the redistribution layers or a frequency selective surface.

According to some embodiments herein, the shielding structure may be a component with frequency selective material mounted on the top layer of the redistribution layers around an opening of the top layer above the signal pad. The component with frequency selective material may be over molded or extended to the top of mold.

According to some embodiments herein, the shielding structure may be a layer of frequency selective material applied on the surface of the top layer of the redistribution layers before molding.

According to some embodiments herein, the shielding structure may be a number of metal plated through mold vias (TMV) created on the top layer of the redistribution layers around an opening of the top layer above the signal pad.

According to some embodiments herein, the TMV shielding structure may comprise a shield cover on the top of the TMV.

According to some embodiments herein, the shielding structure may be a number of soldered pins mounted on the top layer of the redistribution layers around an opening of the top layer above the signal pad.

According to some embodiments herein, the shielding structure may be a metalized cage structure filled with dielectric material formed on the top layer of the redistribution layers around an opening of the top layer above the signal pad. The top of the metalized cage structure may be covered. The top of the metalized cage structure may be extended to the top of mold.

According to some embodiments herein, the shielding structure may be a shielding cage with bumps created under the integrated circuit and above the signal pad.

According to one aspect of embodiments herein, the object is achieved by a package for assembling one or more integrated circuits and routing signals of the one or more integrated circuits using multiple redistribution layers, wherein a top layer of the redistribution layers is facing the integrated circuit, a bottom layer of the redistribution layers is an interface layer facing a substrate or PCB. The package is characterized in that a shielding structure is provided on the top layer of the redistribution layers above a signal pad of an integrated circuit, wherein the signal pad is on the bottom layer of the redistribution layers and is used for routing high-frequency or high-speed signals.

In other words, embodiments herein provide an improved design technique using multiple dies or chiplets solutions offered in the HDFO package in combination with the following techniques:
Meshing a top layer of the RDL to prevent the RF signals from escaping but the density of the mesh is still large enough to reduce the parasitic capacitance.
Placing a component with frequency selective material on top of the redistribution layers and be either over molded or extend to the top of the mold.
Appling a layer of frequency selective material on the surface of the top layer of the redistribution layers before molding.
Using through-mold vias around the RDL top layer opening area, i.e. around an anti-pad, to create a shielding cage for the RF signals.
Adding a metal cage structure above the RDL top layer opening area, i.e. above an anti-pad, that is shielding the RF signals and the large distance from the signal pad to the cage structure minimizes the parasitic capacitance between the cage and the signal pad.
If a pad needs to be placed under a die, opening up in RDL and building a shielding cage with bumps and conducting layer on the die.

Some advantages of the embodiments herein include but not limited to the following:
The use of HDFO package in combination with RDL for integration of beamforming IC under an antenna and routing high-frequency and high-speed signals can minimize silicon area and lower power consumption.
The parasitic capacitance is reduced by meshing the top layer of the RDL.
The high-frequency and high-speed digital signals can be shielded by creating a shielding cage with through-mold vias (TMV) or soldered pins around the RDL top layer opening or by adding a metal cage structure on the RDL top layer above the RDL top layer opening, which can reduce electro-magnetic coupling to and from the sensitive high-frequency and high-speed digital signals and therefore reduce RF spurious signals or noise.

Therefore, embodiments herein provide an improved design technique for assembling dies or chiplets and routing sensitive high-frequency and high-speed signals with respect to reducing spurious signals, noise, silicon area, power consumption, parasitic capacitance etc.

### BRIEF DESCRIPTION OF THE DRAWINGS

Examples of embodiments herein are described in more detail with reference to attached drawings in which:

FIG. 1 is a cross-section view of an example HDFO package;

FIG. 2 is a cross-section view of a part of HDFO package according to prior art;

FIGS. 3 (a), (b) and (c) are cross-section views of a part of HDFO package according to a first embodiment herein;

FIGS. 4 (a), (b), (c) (d) are cross-section views of a part of HDFO package according to a second embodiment herein;

FIGS. 5 (a), (b), (c) are cross-section views of a part of HDFO package according to a third embodiment herein;

FIG. 6 is a cross-section view of a part of HDFO package according to a fourth embodiment herein; and

FIG. 7 is a block diagram illustrating an electronic device in which a package according to embodiments herein may be implemented.

### DETAILED DESCRIPTION

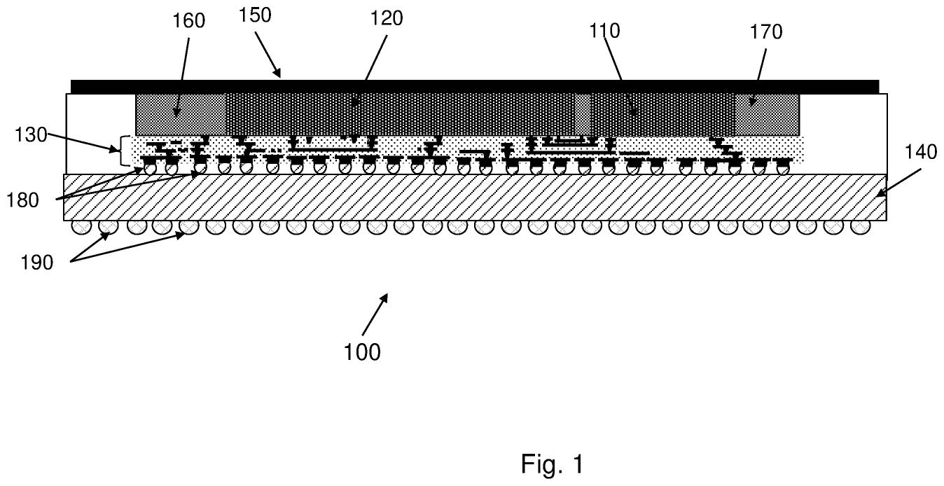

FIG. 1 shows a cross-section view of an example HDFO package 100 with multiple dies solution. As shown in FIG. 1, several dies/chiplets, e.g. RF die 110, digital die 120, are assembled on RDL 130 comprising multiple layers in the HDFO package 100. Dies are flip-chiped and assembled on the RDL 130 and then assembled onto a laminate multilayer substrate 140. A top layer of the redistribution layers is hereby referred to a layer facing the die, and a bottom layer of the redistribution layers is referred to an interface layer facing a substrate or Printed Circuit Board (PCB). The dielectric between RDL layers are typically ˜10 μm or less. The HDFO package 100 is covered by a lid 150. The empty spaces 160, 170 in the package is filled with mold compound material on the RDL 130. There is a Ball Grid Array (BGA) 180 at the bottom of the RDL for connecting the RDL to the substrate 140 and a BGA 190 at the bottom of the substrate 140 for connecting to a HDI laminate or a Printed Circuit Board (PCB). A die or chip customized and manufactured for a particular use is referred to as an application-specific integrated circuit (ASIC) which is an integrated circuit (IC) chip for a specific application rather than intended for general-purpose use. For example, a chip designed to run in a digital voice recorder or a high-efficiency video codec is a digital ASIC, a chip designed to process RF signals is an RF ASIC. ASIC chips are typically fabricated using metal-oxide-semiconductor (MOS) technology.

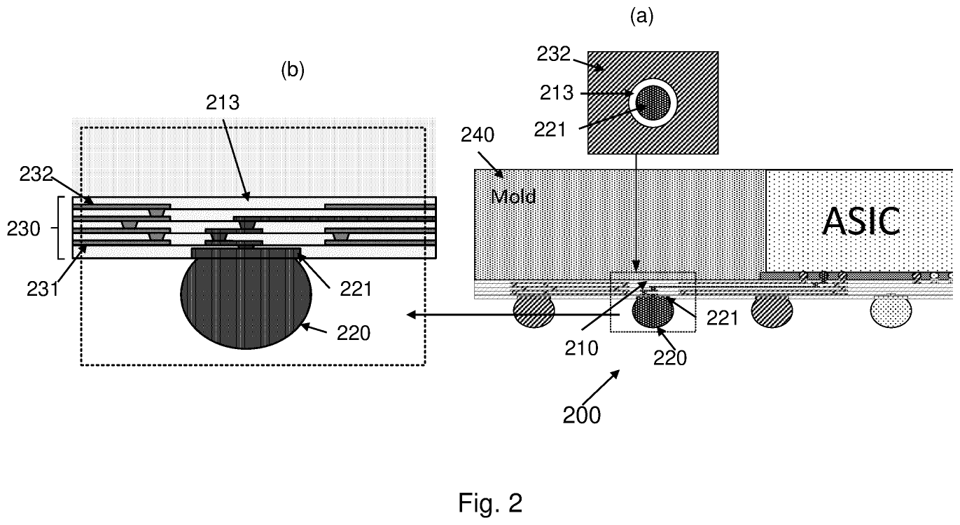

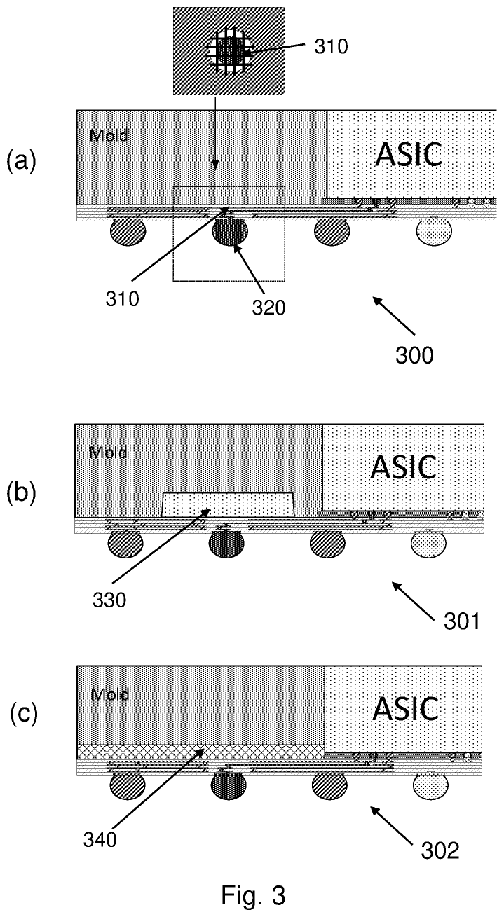

FIG. 2 shows a cross-section view of a part of HDFO package 200, where an anti-pad 210 is created above an RF signal ball 220 is shown. The RF signal ball is a solder ball used for connecting RF signals, one surface of the RF signal ball 220 is connected to an RF signal pad 221 on RDL 230 bottom layer 231, i.e. an interface layer that is used to interface 35 to the next package level of a PCB or a HDI laminate via the solder ball 220 and the other surface of the RF signal ball 220 is connected to or assembled onto a substrate or printed circuit board (PCB) (not shown). The opening in the RDL 230 top metal layer 232 above the signal ball is facing mold compound 240. A top view of the anti-pad 210 is show in FIG. 2 (a) and an enlarged cross-section view of the anti-pad 210 with RF signal ball 220 is shown in FIG. 2 (b). As shown in FIG. 2(a), 232 is GND plane on the RDL top layer, 221 is the RF signal pad on the RDL bottom layer 231 seen from the top, 213 is the opening in the GND plane on the RDL top layer. As can be seen, the RF signal ball/pad 220/221 is exposed, the electro-magnetic coupling in mold 240 may leak to outside or to other nearby exposed signals risking of signal leakages from or to the sensitive RF signals.

FIG. 3 (a) shows a cross-section view of a part of HDFO package 300 according to a first example embodiment herein, where a shielding structure 310 or a modified anti-pad is created above a signal ball 320 e.g. an RF signal ball, according to embodiments herein. The shielding structure 310 in this example is a meshed RDL top layer above the signal ball. As shown in FIG. 3 (a), the top layer of the RDL is meshed to prevent the RF signal from escaping instead of a totally opening of the top layer above the signal ball. The size of opening in the mesh 310 or the density of mesh is determined depending on the wavelength or frequency of the RF signal. There is a trade off between preventing RF signal leakages and reducing parasitic capacitance when designing the mesh. The size of the opening in the mesh 310 or the density of mesh 310 is made large enough to reduce the parasitic capacitance between the mesh 310 and the signal ball/pad.

To prevent unintended radiation of a specific frequency band out from the opening in the top layer above the signal ball, a frequency selective surface may also be used. The frequency selective surface may be mounted as a component on the top layer of the redistribution layers and be either over molded or extend to the top of the mold. FIG. 3 (b) shows a cross-section view of a part of HDFO package 301 with a shielding structure 330. The shielding structure 330 in this example is a component with frequency selective material mounted on the top layer of the redistribution layers around an opening of the top layer above the signal ball. The shielding structure 330 is over molded in this example. However, the shielding structure 330 may extend to the top of the mold (not shown).

The frequency selective surface may also be applied as a layer on the surface of the top layer of the redistribution layers before molding. FIG. 3 (c) shows a cross-section view of a part of HDFO package 302 with a shielding structure 340. The shielding structure 340 in this example is a layer of frequency selective material applied on the surface of the top layer of the redistribution layers before molding.

The shielding structure of frequency selective surface 330, 340 is intended to act as a spatial filter in order to block radiation of signals in a specific frequency band. The shielding structure 330, 340 may both prevent signal from radiating out from the signal pad through the opening in the top layer of the redistribution layer or prevent noise or interfering signals from outside to reach the signal pad within the redistribution layers. The frequency range and frequency selectivity of the shielding structure 330, 340 may be determined based on operating frequency of ASIC chips. The frequency characteristic of the shielding structure 330, 340 may be a band-stop, a band-pass, a high-pass or a low-pass filter depends on application scenarios.

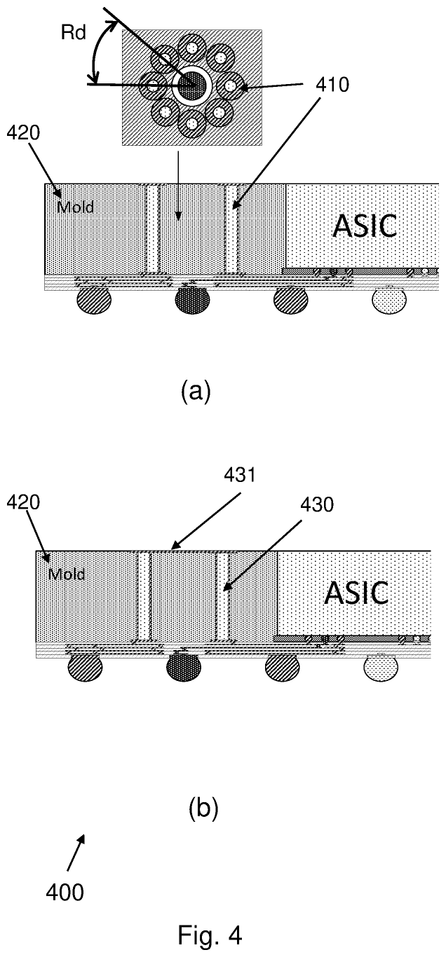

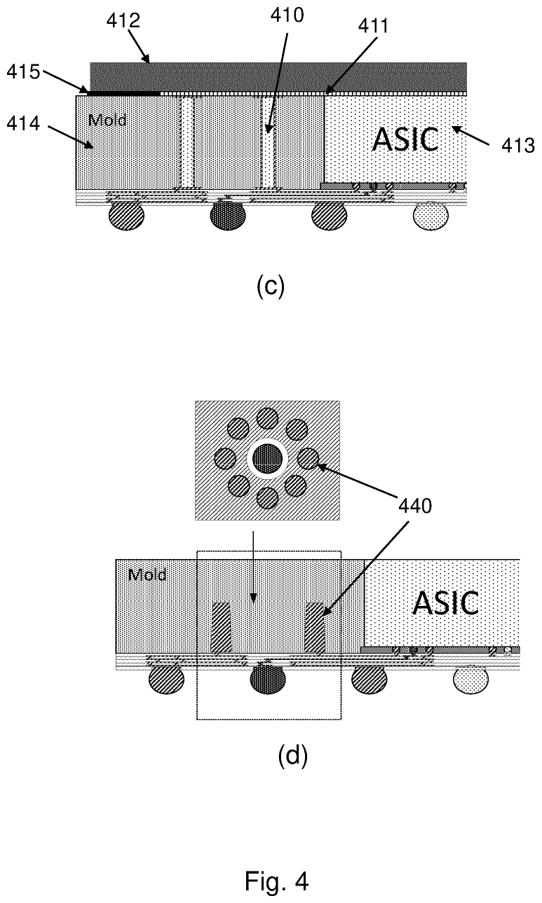

FIG. 4 (a) shows a cross-section view of a part of HDFO package 400 according to a second example embodiment herein, where a shielding structure 410 is created around opening of an anti-pad. The shielding structure 410 in this example is a number of through mold vias (TMV) created around the anti-pad. TMV is a process typically used for building package on package solutions.

The top of the TMV may be connected together with a metallization on the top-side of mold 420 to form a shield cover over the exposed signal ball/pad. FIG. 4 (b) shows a shielding structure 430 with a shield cover 431.

FIG. 4(c) shows a cross-section view of a part of HDFO package, where the shielding structure 410 is covered by thermal interface material (TIM) 411 filled between lid 412 and die 413. Between lid 412 and mold 414 is attach material 415, e.g. glue. The lid 412 in this case may act as a shield cover more like the shield cover 431 in FIG. 4(b) and the signal pad will not be exposed upward. The difference is that there might not be any galvanic contact between the shielding structure 410 and the lid 412 due to that the TIM 411 is not necessarily conducting.

The shielding structure 410 may be metal plated or made by metal filled via holes but may also be a soldered pin mounted on the RDL top layer.

FIG. 4 (d) shows a shielding structure 440 with a number of soldered pins mounted on the RDL top layer around opening of an anti-pad, where the soldered pins do not need to go through mold 420.

The diameter of the vias or metal pin is set by design rules. The distance between the vias or metal pins is determined by the wavelength or frequency of the RF signal. The preferred minimum radial distance Rd, as shown in FIG. 4(a), between the vias is related to the wavelength or frequency of the RF signal.

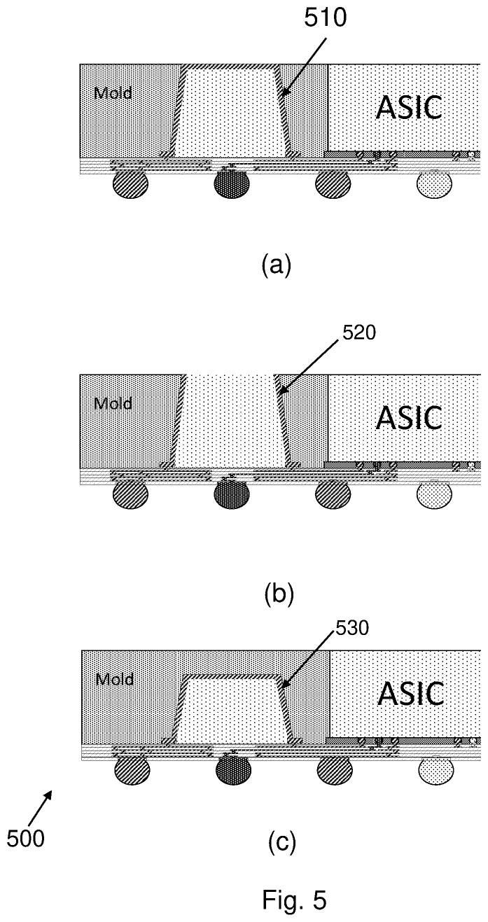

FIG. 5 (a) shows a cross-section view of a part of HDFO package 500 according to a third example embodiment herein, where a shielding structure 510 is created around opening of an anti-pad. The shielding structure 510 in this example is a metalized cage structure filled with dielectric material. The metalized cage structure may be soldered onto the RDL.

In case of a die first fanout design, the metalized cage can be formed by opening the mold and plating the area with metal and filling it with mold again.

The metalized cage structure does not need to extend to top of the mold and does not need to be covered. FIG. 5 (b) shows a shielding structure 520 where the top of the metalized cage structure is not covered. FIG. 5 (c) shows a shielding structure 530 where the metalized cage structure is not extended to the top of mold.

The metalized cage structures 510, 520, 530 can shield the RF signals and the large distance from the signal pad to the cage structure minimizes the parasitic capacitance on the signal pad.

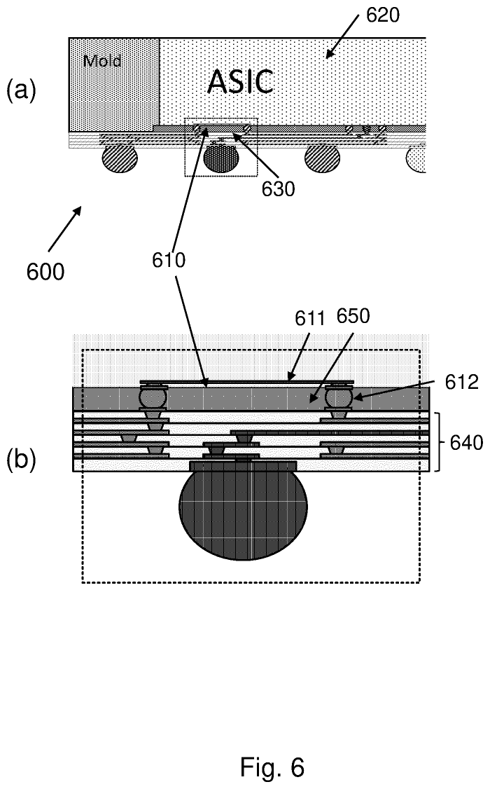

If a pad needs to be placed under a die, one may open up in RDL and build a shielding cage with bumps and conducting layer on the die. FIG. 6 (a) shows a cross-section view of a part of HDFO package 600 according to a fourth example embodiment herein, where a shielding structure 610 is created under a die 620 and above an anti-pad 630. As shown in FIG. 6 (b), the shielding structure 610 comprises a GND metal layer 611 either meshed or as a whole piece under the die 620. The shielding structure 610 further comprises a bump or ball 612 connecting the die and RDL 640. Between the die and the RDL top layer is filled with underfill material 650, e.g. a dielectric material that acts as a glue between two components, e.g. the die 620 and RDL 630 in this case. It is used to reduce the mechanical stress on the solder balls and also acts as a protection to ICs.

All the example embodiments with the shielding structures 310, 330, 340, 410, 430, 440, 510, 520, 530, 610 presented in FIGS. 3-6 may also be implemented in other package technologies than HDFO in case of use of very thin buildup layers.

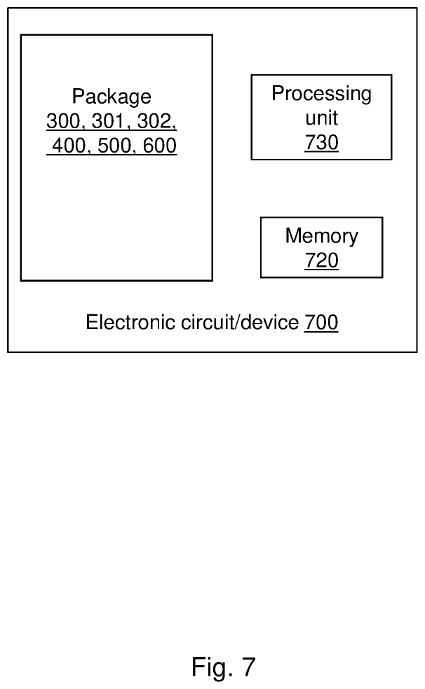

The shielding structures 310, 330, 340, 410, 430, 440, 510, 520, 530, 610 according to the embodiments herein for reducing RF signal leakages and protecting sensitive signals may be employed in various packages for assembling one or more integrated circuits, e.g. ASICs. According to embodiments herein, a shielding structure 310, 330, 340, 410, 430, 440, 510, 520, 530, 610 may be provided in the package on a top layer of the redistribution layers above a signal pad of an integrated circuit. The signal pad is on a bottom layer of the redistribution layers and is for routing high-frequency or high-speed signals. The package with shielding structures 310, 330, 340, 410, 430, 440, 510, 520, 530, 610 according to the embodiments herein may be used to build various electronic circuits or devices. FIG. 7 shows a block diagram for an electronic device 700. The electronic device 700 may comprise other units, where a memory 720, a processing unit 730 are shown. The electronic device 700 may be any device where one or more integrated circuits need to be used, such as a user equipment or a mobile device, a wireless communication device, a radio base station, an access point, a relay or a repeater for a cellular communication system.

To summarize, to prevent the RF signals from escaping and protect sensitive signals, a method for shielding a signal pad of an integrated circuit in a package with multiple redistribution layers is provided. The signal pad is on a bottom layer of the redistribution layers and is for routing high-frequency or high-speed signals. Various shielding structures 310, 330, 340, 410, 430, 440, 510, 520, 530, 610 according to embodiments herein may be provided on a top layer of the redistribution layers above the signal pad. The method for shielding a signal pad of an integrated circuit may comprise:
Meshing a top layer of the RDL above the signal pad;
Placing a component with frequency selective material on top of the redistribution layers around an opening of the top layer above the signal pad, the component with frequency selective material may be over molded or extended to the top of mold;
Appling a layer of frequency selective material on the surface of the top layer of the redistribution layers before molding;
Using through-mold vias or soldered pins around the RDL top layer opening area above the signal pad to create a shielding cage for the RF signals;
Adding a metal cage structure above the RDL top layer opening area above the signal pad to prevent RF signal leakages.

If a pad needs to be placed under a die, opening up in RDL and building a shielding cage with bumps and conducting layer on the die.

Some advantages of the embodiments herein include but not limited to the following:
The use of HDFO package in combination with RDL for integration of ICs under an antenna and routing high-frequency and high-speed signals can minimize silicon area and lower power consumption.
The parasitic capacitance may be reduced by meshing the top layer of the RDL and the meshed top layer can reduce the RF signal leakage.
The high-frequency and high-speed digital signals can be shielded by creating a shielding structure 310, 330, 340, 410, 430, 440, 510, 520, 530, 610 around the RDL top layer opening above a signal pad. In this way, the electro-magnetic coupling is reduced to and from the sensitive high-frequency and high-speed digital signals and therefore RF spurious signals or noise is reduced.

The word “comprise” or “comprising”, when used herein, shall be interpreted as non-limiting, i.e. meaning “consist at least of”.

The embodiments herein are not limited to the above described preferred embodiments. Various alternatives, modifications and equivalents may be used. Therefore, the above embodiments should not be taken as limiting the scope of the invention, which is defined by the appended claims.

### Example Embodiments

Embodiment 1: A method for shielding a signal pad of an integrated circuit in a package with multiple redistribution layers, wherein a top layer of the redistribution layers is facing the integrated circuit, a bottom layer of the redistribution layers is an interface layer facing a substrate or PCB, and the signal pad is on the bottom layer of the redistribution layers and is used for routing high-frequency or high-speed signals, the method comprises:
providing a shielding structure (310, 330, 340, 410, 430, 440, 510, 520, 530, 610) on the top layer of the redistribution layers above the signal pad.
   Embodiment 2: The method according to the embodiment 1, wherein the shielding structure (310) is a meshed top layer of the redistribution layers or a frequency selective surface (330, 340).
   Embodiment 3: The method according to the embodiment 1, wherein the shielding structure (330) is a component with frequency selective material mounted on the top layer of the redistribution layers around an opening of the top layer above the signal pad, and wherein the component with frequency selective material is over molded or extended to the top of mold.
   Embodiment 4: The method according to the embodiment 1, wherein the shielding structure (340) is a layer of frequency selective material applied on the surface of the top layer of the redistribution layers before molding.
   Embodiment 5: The method according to the embodiment 1, wherein the shielding structure (410, 430) is a number of through mold vias, TMV, metal plated or metal filled, created on the top layer of the redistribution layers around an opening of the top layer above the signal pad.
   Embodiment 6: The method according to the embodiment 5, wherein the shielding structure (430) further comprises a shield cover (431) on the top of the TMV.
   Embodiment 7: The method according to the embodiment 1, wherein the shielding structure (440) is a number of soldered pins mounted on the top layer of the redistribution layers around an opening of the top layer above the signal pad.
   Embodiment 8: The method according to the embodiment 1, wherein the shielding structure (510, 520, 530) is metalized cage structure filled with dielectric material formed on the top layer of the redistribution layers around an opening of the top layer above the signal pad.
   Embodiment 9: The method according to the embodiment 8, wherein the top of the metalized cage structure (510, 530) is covered.
   Embodiment 10: The method according to the embodiment 8, wherein the top of the metalized cage structure (530) is extended to the top of mold.
   Embodiment 11: The method according to the embodiment 1, wherein the shielding structure (610) is a shielding cage with bumps created under the integrated circuit and above the signal pad.
   Embodiment 12: A package for assembling one or more integrated circuits and routing signals of the one or more integrated circuits using multiple redistribution layers, wherein a top layer of the redistribution layers is facing the integrated circuit, a bottom layer of the redistribution layers is an interface layer facing a substrate or PCB, the package is characterized in that a shielding structure (310, 330, 340, 410, 430, 440, 510, 520, 530, 610) is provided on the top layer of the redistribution layers above a signal pad of an integrated circuit, wherein the signal pad is on the bottom layer of the redistribution layers and is used for routing high-frequency or high-speed signals.
   Embodiment 13: The package according to the embodiment 12, wherein the shielding structure is a meshed top layer of the redistribution layers (310) or a frequency selective surface (330, 340).
   Embodiment 14: The method according to the embodiment 12, wherein the shielding structure (330) is a component with frequency selective material mounted on the top layer of the redistribution layers around an opening of the top layer above the signal pad, and wherein the component with frequency selective material is over molded or extended to the top of mold.
   Embodiment 15: The method according to the embodiment 12, wherein the shielding structure (340) is a layer of frequency selective material applied on the surface of the top layer of the redistribution layers before molding.
   Embodiment 16: The package according to the embodiment 12, wherein the shielding structure (410, 430) is a number of through mold vias, TMV, metal plated or metal filled, created on the top layer of the redistribution layers around an opening of the top layer above the signal pad.
   Embodiment 17: The package according to the embodiment 16, wherein the shielding structure (430) further comprises a shield cover (431) on the top of the TMV.
   Embodiment 18: The package according to the embodiment 12, wherein the shielding structure (440) is a number of soldered pins mounted on the top layer of the redistribution layers around an opening of the top layer above the signal pad.
   Embodiment 19: The package according to the embodiment 12, wherein the shielding structure (510, 520, 530) is metalized cage structure filled with dielectric material formed on the top layer of the redistribution layers around an opening of the top layer above the signal pad.
   Embodiment 20: The package according to the embodiment 19, wherein the top of the metalized cage structure (510, 530) is covered.
   Embodiment 21: The package according to the embodiment 19, wherein the top of the metalized cage structure (530) is extended to the top of mold.
   Embodiment 22: The package according to the embodiment 12, wherein the shielding structure (610) is a shielding cage with bumps created under the integrated circuit and above the signal pad.
   Embodiment 23: An electronic circuit or device comprising a package according to any one of the embodiments 12-22.

1. A method for shielding a signal pad of an integrated circuit in a package with multiple redistribution layers, wherein a top layer of the redistribution layers is facing the integrated circuit, a bottom layer of the redistribution layers is an interface layer facing a substrate or printed circuit board, PCB, and the signal pad is on the bottom layer of the redistribution layers and is used for routing high-frequency or high-speed signals, the method comprises:
providing a shielding structure on the top layer of the redistribution layers above the signal pad.

2. The method according to claim 1, wherein the shielding structure is a meshed top layer of the redistribution layers or a frequency selective surface.

3. The method according to claim 1, wherein the shielding structure is a component with frequency selective material mounted on the top layer of the redistribution layers around an opening of the top layer above the signal pad, wherein the component with frequency selective material is over molded or extended to the top of mold.

4. The method according to claim 1, wherein the shielding structure is a layer of frequency selective material applied on the surface of the top layer of the redistribution layers before molding.

5. The method according to claim 1, wherein the shielding structure is a number of through mold vias, TMV, metal plated or metal filled, created on the top layer of the redistribution layers around an opening of the top layer above the signal pad.

6. The method according to claim 5, wherein the shielding structure further comprises a shield cover on the top of the TMV.

7. The method according to claim 1, wherein the shielding structure is a number of soldered pins mounted on the top layer of the redistribution layers around an opening of the top layer above the signal pad.

8. The method according to claim 1, wherein the shielding structure is metalized cage structure filled with dielectric material formed on the top layer of the redistribution layers around an opening of the top layer above the signal pad.

9. The method according to claim 8, wherein the top of the metalized cage structure is covered.

10. The method according to claim 8, wherein the top of the metalized cage structure is extended to the top of mold.

11. The method according to claim 1, wherein the shielding structure is a shielding cage with bumps created under the integrated circuit and above the signal pad.

12. A package for assembling one or more integrated circuits and routing signals of the one or more integrated circuits using multiple redistribution layers, the package comprising:
a top layer of the redistribution layers is facing the integrated circuit, a bottom layer of the redistribution layers is an interface layer facing a substrate or a printed circuit board, PCB; and
a shielding structure is provided on the top layer of the redistribution layers above a signal pad of an integrated circuit, wherein the signal pad is on the bottom layer of the redistribution layers and is used for routing high-frequency or high-speed signals.

13. The package according to claim 12, wherein the shielding structure is a meshed top layer of the redistribution layers or a frequency selective surface.

14. The package according to claim 12, wherein the shielding structure is a component with frequency selective material mounted on the top layer of the redistribution layers around an opening of the top layer above the signal pad, and wherein the component with frequency selective material is over molded or extended to the top of mold.

15. The package according to claim 12, wherein the shielding structure is a layer of frequency selective material applied on the surface of the top layer of the redistribution layers before molding.

16. The package according to claim 12, wherein the shielding structure is a number of through mold vias, TMV, metal plated or metal filled, created on the top layer of the redistribution layers around an opening of the top layer above the signal pad.

17. The package according to claim 16, wherein the shielding structure further comprises a shield cover on the top of the TMV.

18. The package according to claim 12, wherein the shielding structure is a number of soldered pins mounted on the top layer of the redistribution layers around an opening of the top layer above the signal pad.

19. The package according to claim 12, wherein the shielding structure is metalized cage structure filled with dielectric material formed on the top layer of the redistribution layers around an opening of the top layer above the signal pad.

20. The package according to claim 19, wherein the top of the metalized cage structure is covered.

21.-23. (canceled)
